(19) United States
(12) Patent Application Publication
(10) Pub. No.: US 2026/0344460 A1
(43) Pub. Date: Oct. 29, 2026

(54) REDISTRIBUTION STRUCTURES WITH SEAL RINGS AND THE METHODS OF FORMING THE SAME

(71) Applicant: Taiwan Semiconductor Manufacturing Co., Ltd., Hsinchu (TW)

(72) Inventors: Hsien-Wei Chen, Hsinchu (TW); Chieh-Lung Lai, Taichung City (TW); Meng-Liang Lin, Hsinchu (TW); Kathy Wei Yan, Hsinchu (TW)

(21) Appl. No.: 19/727,408

(22) Filed: Jul. 1, 2026

Related U.S. Application Data
(63) Continuation of application No. 18/938,498, filed on Nov. 6, 2024.
(60) Provisional application No. 63/675,892, filed on Jul. 26, 2024.

(51) Int. Cl. H10W 70/60; H10W 42/00; H10W 70/05; H10W 74/10; H10W 90/00

(52) U.S. Cl. CPC H10W 70/611; H10W 42/00; H10W 70/05; H10W 90/00; H10W 90/401; H10W 70/60; H10W 74/141

(57) ABSTRACT

A method includes forming an interconnect structure and an interposer. The interconnect structure comprises a first plurality of redistribution lines, and a wafer seal ring encircling the first plurality of redistribution lines. The interposer comprises a second plurality of redistribution lines, and a plurality of die seal rings encircling the second plurality of redistribution lines. The method includes bonding a first plurality of package components to the interposer, and bonding a second plurality of package components to the interconnect structure. The first plurality of package components are electrically connected to the second plurality of package components through the interposer and the interconnect structure.

### PRIORITY CLAIM AND CROSS-REFERENCE

This application is a continuation of U.S. patent application Ser. No. 18/938,498, filed Nov. 6, 2024, and entitled “REDISTRIBUTION STRUCTURES WITH SEAL RINGS AND THE METHODS OF FORMING THE SAME,” which claims the benefit of U.S. Provisional Application No. 63/675,892, filed on Jul. 26, 2024, and entitled “ORGANIC INTERPOSER SILICON ON WAFER;” which application are hereby incorporated herein by reference.

### BACKGROUND

Interconnect dies have been used for electrically interconnecting device dies and packages. The interconnect dies may be embedded in Chip-on-wafer-on-substrate packages. The wafers in the package are often interposers.

With the increasingly demanding requirement of computing power, the interposers are being made increasingly larger. This posts problems because the overlay window is narrower when the interposers are larger. The problems such as cold joint are more likely to occur.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 illustrate the cross-sectional views of intermediate stages in the formation of a package in accordance with some embodiments.

FIG. 7 illustrates a package in accordance with some embodiments.

FIGS. 8-15 illustrate the cross-sectional views of intermediate stages in the formation of a package in accordance with some embodiments.

FIGS. 16, 17, and 18 illustrate some packages in accordance with some embodiments.

FIGS. 19 and 20 illustrate the top views of some packages in accordance with some embodiments.

FIG. 21 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including an interconnect structure and an interposer, the respective seal rings, and the method of forming the same are provided. In accordance with some embodiments, a wafer seal ring is formed in the interconnect structure, and a die seal ring (or die seal rings) is formed in the interposer. Package components including device dies may be incorporated in the package, and may be interconnected through the interconnect structure and the interposer. By forming the wafer seal ring and the die seal ring(s), the warpage of the package may be reduced.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

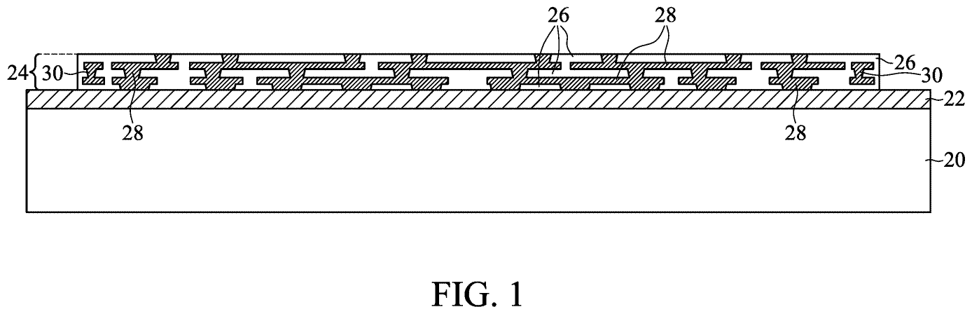

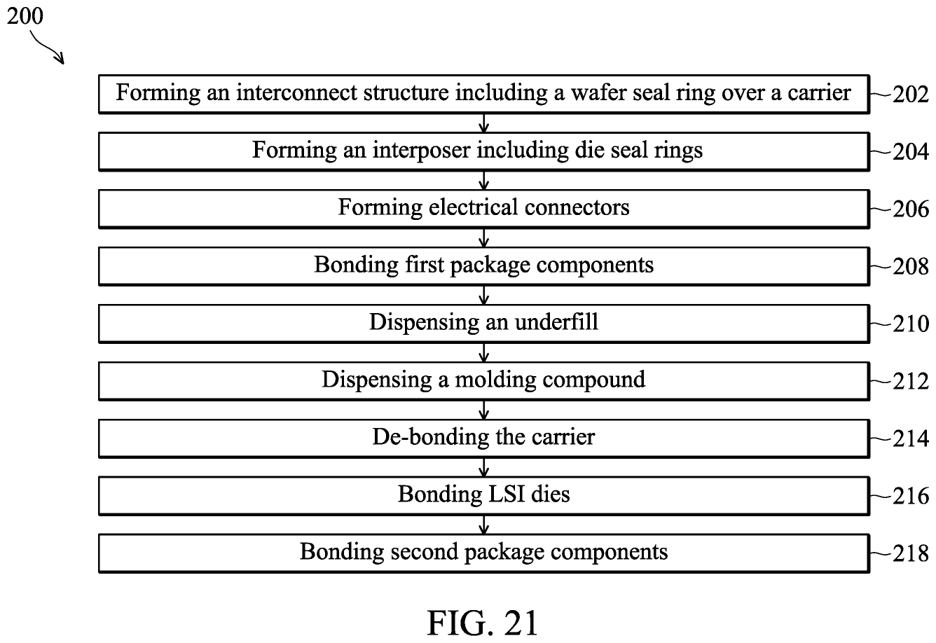

FIGS. 1 through 6 illustrate the cross-sectional views of intermediate stages in the formation of a package comprising a wafer seal ring and die seal rings in accordance with some embodiments of the present disclosure. The corresponding processes are also reflected schematically in the process flow shown in FIG. 21.

Referring to FIG. 1, carrier 20 is provided, and release film 22 is coated on carrier 20. Carrier 20 is formed of a transparent material, and may be a glass carrier, a ceramic carrier, an organic carrier, or the like. Release film 22 is in physical contact with the top surface of carrier 20. Release film 22 may be formed of a Light-To-Heat-Conversion (LTHC) coating material. Release film 22 may be applied onto carrier 20 through coating.

In accordance with some embodiments, the LTHC coating material is capable of being decomposed under the heat of light/radiation (such as a laser beam), and may be able to release carrier 20 from the structure placed and formed thereon. In accordance with some embodiments, a buffer dielectric layer (not shown) may be formed over release film 22. The buffer dielectric layer may comprise polybenzoxazole (PBO), polyimide, benzocyclobutene (BCB), or the like. In accordance with alternative embodiments, no buffer layer is formed.

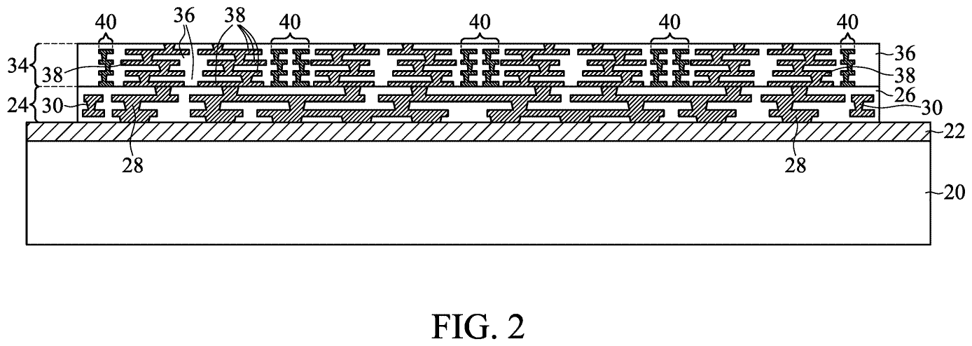

Further referring to FIG. 1, interconnect structure 24 is formed over carrier 20 (and over the buffer layer, when formed). The respective process is illustrated as process 202 in the process flow 200 as shown in FIG. 21. Interposer 34 is then formed over interconnect structure 24, as shown in FIG. 2. The respective process is illustrated as process 204 in the process flow 200 as shown in FIG. 21. Throughout the description, interconnect structure 24 and interposer 34 are alternatively referred to as redistribution structures.

In accordance with some embodiments, interconnect structure 24 may be used for the global lateral connection such as the interconnection of the package components overlying interposer 34 and/or the interconnection of the package components underlying interconnect structure 24. Interposer 34, on the other hand, may be used for local interconnection, for example, the interconnection of connection of the features in a package component, and/or the connection of the package components underlying interconnect structure 24 to the package components overlying interposer 34.

In accordance with some embodiments, interconnect structure 24 and interposer 34 include dielectric layers 26 and dielectric layers 36, respectively. The boundaries between neighboring dielectric layers 26 (and/or the boundaries between neighboring dielectric layers 36) are not shown, while the boundaries may be (or may not be), distinguishable.

In accordance with some embodiments, dielectric layers 26 are formed of a photo-sensitive polymer(s) such as PBO, polyimide, BCB, or the like, with each of the dielectric layers 26 being formed of a homogenous dielectric material. In accordance with alternative embodiments, dielectric layers 26 are formed of a non-photo-sensitive material(s) such as a molding compound(s), a molding underfill(s), silicon oxide, silicon nitride, or the like. The formation of each of dielectric layers 26 may include dispensing a corresponding dielectric layer in a flowable form, and then curing the dielectric layer. Alternatively, dielectric layers 26 may be formed through deposition processes.

In accordance with some embodiments, dielectric layers 36 are formed of materials selected from the same group of candidate materials of dielectric layers 26, and may include PBO, polyimide, BCB, molding compound, molding underfill, or the like. In accordance with alternative embodiments, dielectric layers 36 may comprise inorganic materials such as silicon oxide, silicon nitride, silicon oxynitride, or the like.

RDLs 28 are formed in dielectric layers 26, and RDLs 38 are formed in dielectric layers 36. RDLs 28 and 38 electrically and signally interconnect the package components (such as device dies) as a system. In accordance with some embodiments, RDLs 28 are thicker and/or wider (when viewed from top) than RDLs 38, and may be used for long-range electrical routing, while RDLs 38 may be used for short-range electrical routing.

An example formation process of dielectric layers 26 and RDLs 28 are discussed as follows as an example. First, as shown in FIG. 1, a first dielectric layer (the bottom dielectric layer under the bottom one of dielectric layers 26) is deposited over carrier 20 (or over the buffer layer if formed). The dielectric layer 26 is then patterned to form openings, through which the underlying buffer layer or release film 22 is exposed. The patterning process may be performed through a photo lithography process including a light-exposure process on the dielectric layer 26, and developing the dielectric layer 26.

Next, a metal seed layer (not shown) is deposited, for example, through a Physical Vapor Deposition (PVD) process. The metal seed layer may include a titanium layer and a copper layer over the titanium layer. Alternatively, the metal seed layer may be a copper layer. A plating mask (not shown), which may be comprise photoresist, is then formed on the patterned dielectric layer 26, and is also patterned. A plating process is then performed to deposit a metallic material (such as copper, aluminum, aluminum copper, or the like) in the openings in the plating mask. The plating mask is then removed, followed by the etching of the underlying metal seed layer, leaving RDLs 28.

As shown in FIG. 1, an RDL layer 28 (which includes a plurality of RDLs 28 at the same level) is formed, and includes line portions overlying the bottom dielectric layer 26 and via portions in the bottom dielectric layer 26. This process may be repeated to form a plurality of dielectric layers 26 and the corresponding RDLs 28. Accordingly, distinguishable interfaces may be formed between neighboring dielectric layers 26, wherein the distinguishable interfaces may be at the same levels wherein metal lines are joined to the respective underlying vias.

In accordance with alternative embodiments, dielectric layers 26 and RDLs 28 are formed using an alternative process, in which the line portions are formed before the formation of the respective overlying via portions. In an example formation process, a metal seed layer is deposited, followed by the formation and the patterning of a first plating mask (not shown), which may be a photoresist. A first plating process is then performed to plate the line portions of RDLs 28. The first plating mask is then removed. Next, without etching the metal seed layer, a second plating mask (not shown) is formed, which may also be a photoresist. A second plating process is then performed to plate the via portions of the RDLs 28.

The second plating mask is then removed, followed by the etching of the underlying metal seed layer not covered by the line portions of RDLs 28. A layer of RDLs 28 and the overlying vias are thus formed. Next, another dielectric layer 26, for example, a molding compound, PBO, or polyimide, is disposed and cured. A planarization process is then performed, so that the top surfaces of the via portions of RDLs 28 are level with the top surface of the dielectric layer 26.

This process may be repeated to form a plurality of dielectric layers 26 and the corresponding RDLs 28. Accordingly, distinguishable interfaces may be formed between neighboring dielectric layers 26. The distinguishable interfaces may be at the same levels wherein the line portions contact the respective underlying vias, and may be distinguishable due to the planarization processes.

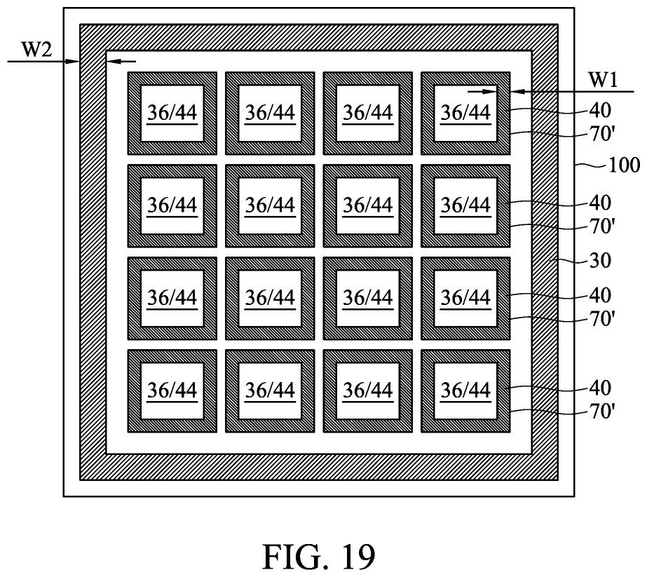

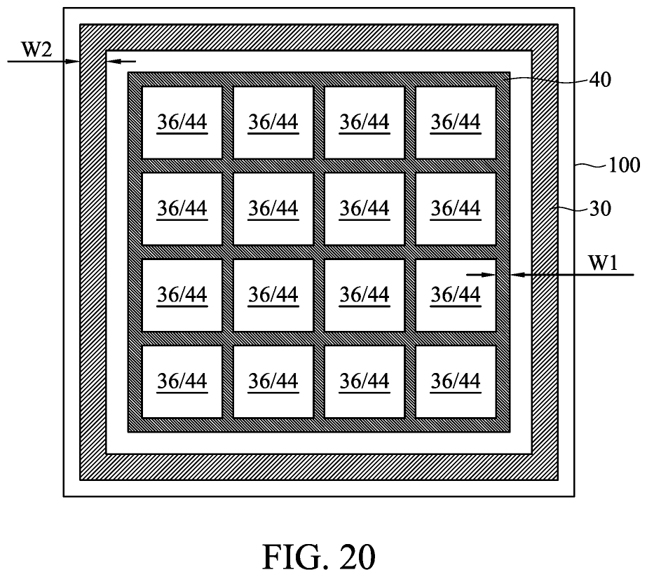

In the same processes for forming RDLs 28, wafer seal ring 30 is formed. Wafer seal ring 30 is such named since it is formed proximate the peripherals of the resulting reconstructed wafer or package, as shown in FIGS. 19 and 20, and do not extend into the inner regions the reconstructed wafer. In accordance with some embodiments, wafer seal ring 30 is formed layer by layer, and in the same processes for forming RDLs 28.

Interposer 34 is formed over interconnect structure 24, and includes dielectric layers 36 and RDLs 38. In accordance with some embodiments, dielectric layers 36 and RDLs 38 are formed through the same candidate groups of methods as the formation of dielectric layers 26 and RDLs 28, respectively.

In accordance with some embodiments, dielectric layers 26 are thicker than dielectric layers 36. For example, the thickness of each of dielectric layers 26 may be in the range between about 10 μm and about 40 μm, while the thickness of each of dielectric layers 36 may be in the range between about 1 μm and about 10 μm.

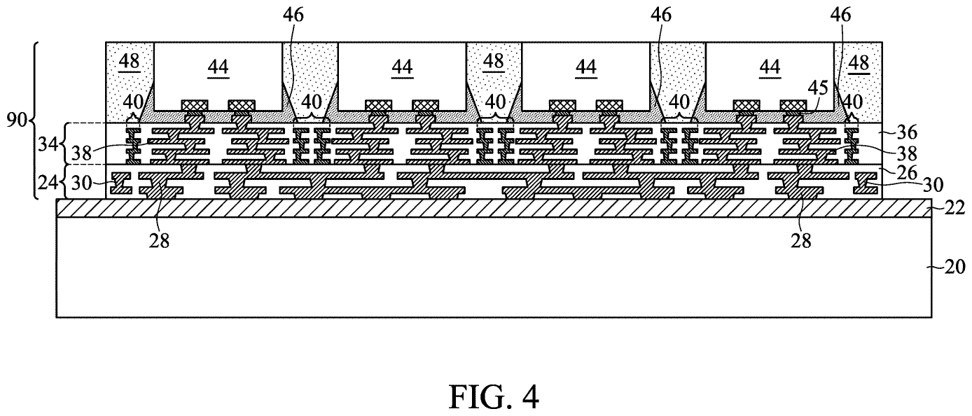

In accordance with some embodiments, in the same processes for forming RDLs 38, die seal rings 40 are formed. Die seal rings 40 are such named since a plurality of seal rings may be formed, each corresponding to one of the device dies to be bonded in subsequent processes. For example, as shown in FIG. 4, each of die seal ring 40 may encircle a region that is directly under one of package components 44 (which may include device dies).

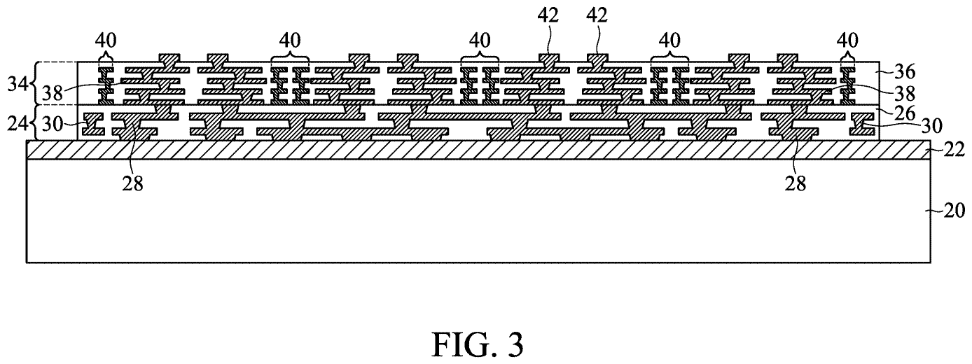

FIG. 3 illustrates the formation of top electrical connectors 42 (also referred to as Under-Bump Metallurgies (UBMs)). The respective process is illustrated as process 206 in the process flow 200 as shown in FIG. 21. In accordance with some embodiments, the formation process may include etching a top dielectric layer 38 to reveal the metal pads in the top RDLs 36, depositing a metal seed layer, forming a patterned plating mask, and performing a plating process(es). The plating mask is then removed, followed by the etching of the metal seed layer. The plating mask may be formed of a photo-sensitive material such as a photoresist. The patterning of the plating mask may be through a light-exposure process followed by a development process.

Electrical connectors 42 may include metal pillars, and may or may not include solder layers. The solder layers, if formed, may also be plated on the metal pillars, and are then reflowed.

FIG. 4 illustrates the bonding of package components 44, which are bonded to the underlying interposer 34 through electrical connectors 42. The respective process is illustrated as process 208 in the process flow 200 as shown in FIG. 21. In accordance with some embodiments, the bonding may be performed through solder regions 45, which may have the height smaller than about 100μm, or smaller than about 50μm. Alternatively, the bonding may include metal-to-metal direct bonding or hybrid bonding that includes both of the metal-to-metal direct bonding between metallic features and fusion bonding between dielectric layers.

Package components 44 may include logic dies (such as computing dies), memory dies (such as Dynamic Random-Access Memory (DRAM) dies or Static Random-Access Memory (SRAM) dies), packages (including device dies that have already been packaged in), Input-output (IO) dies, digital dies, analog dies, die stacks such as High-Bandwidth Memory (HBM) blocks, or the like. Package components 44 may also include some passive device dies such as independent passive device (IPD) dies.

After package components 44 are bonded, underfill 46 may be dispensed into the gaps between package components 44 and the underlying interposer 34. The respective process is illustrated as process 210 in the process flow 200 as shown in FIG. 21. Molding compound 48 is then dispensed to encapsulate package components 44 therein. The respective process is illustrated as process 212 in the process flow 200 as shown in FIG. 21. Underfill 46 and molding compound 48 are individually and collectively referred to as encapsulants. In accordance with some embodiments, underfill 46 and molding compound 48 may include base materials such as epoxies, polymers, and/or resins, and filler particles in the corresponding base materials. The filler particles may comprise silica, aluminum oxide, boron nitride, or the like.

A planarization process such as a Chemical Mechanical Polish (CMP) process or a mechanical polish process is performed, so that the top surfaces of package components 44 may be exposed. The exposed surfaces of package components 44 may be the silicon substrates of the respective device dies. The resulting structure over release film 22 is referred to as reconstructed wafer 90.

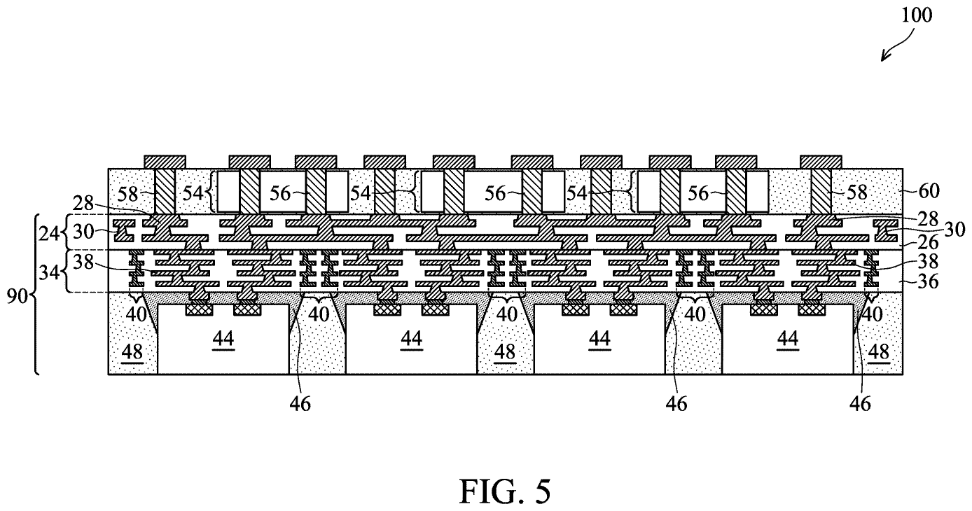

In a subsequent process, reconstructed wafer 90 is de-bonded from carrier 20. The respective process is illustrated as process 214 in the process flow 200 as shown in FIG. 21. The de-bonding may be performed, for example, by projecting a light beam (such as a laser beam) on release film 22, and the light beam penetrates through the transparent carrier 20. The release film 22 is thus decomposed, and reconstructed wafer 90 is released from carrier 20. FIG. 5 illustrates a resulting reconstructed wafer 90, which is flipped upside down relative to the structure shown in FIG. 4.

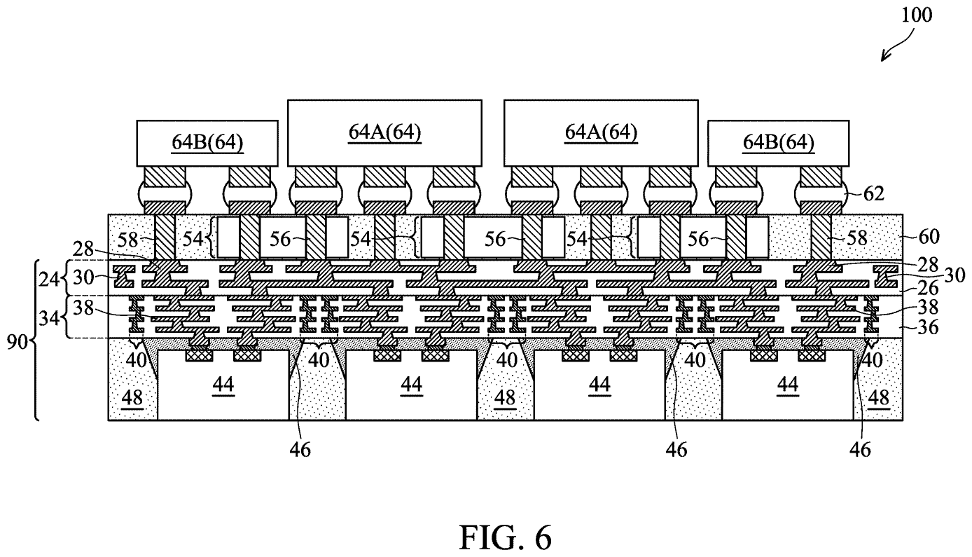

FIG. 5 further illustrates the bonding of device dies 54 to interconnect structure 24. In accordance with some embodiments, device dies 54 may include local silicon interconnect (LSI) dies (which are also referred to a bridge dies) that are used for interconnecting the overlying package components 64 (FIG. 6). The respective process is illustrated as process 216 in the process flow 200 as shown in FIG. 21. Device dies 54 may also include Integrated Voltage Regulators (IVRs) in accordance with some embodiments. Throughout the description, device dies 54 may be referred to as LSI dies, while device dies 54 may also include other types of device dies.

Through-vias 56 may be formed in LSI dies 54 to connect the interconnect structure 24 to the subsequent bonded package components. Encapsulant 60 is formed to encapsulate LSI dies 54 therein. Through-vias 58 may also be formed from redistribution lines 26, and penetrate through encapsulant 60. Encapsulant 60 may comprise molding compound, underfill, or the like.

FIG. 6 further illustrates the bonding of package components 64 (through solder regions 62) to form package 100. The respective process is illustrated as process 218 in the process flow 200 as shown in FIG. 21. In accordance with some embodiments, package components 64 comprise device dies 64A and connectors 64B. In accordance with some embodiments, device dies 64A may include Integrated IVRs, power modules, IPDs, and/or the like. Connectors 64B may include sockets for connecting package 100 to the package components external to the package 100.

In accordance with some embodiments, the package 100 comprises a reconstructed wafer, and is a wafer-level package that is used in the form of a wafer, rather than being cut into a plurality of identical smaller packages. When used (powered up), package 100 may include a circular edge when viewed from the top of package 100. Alternatively, package 100 may be edge-trimmed to remove some or all of the rounded edge portions that do not include circuits, device dies, metal lines, and the like. The resulting package 100 may include rounded edges and straight edges located alternatingly, or include straight edges but not rounded edges.

In the resulting wafer-level package, wafer seal ring 30 is formed to include a plurality of portions, each proximate a respective edge of the package 100. For example, FIGS. 19 and 20 illustrate the top views of packages 100 in accordance with some embodiments. In accordance with some embodiments as shown in FIGS. 19 and 20, packages 100 may have rectangular top-view shapes including four edges, and/or may include rounded edges. Wafer seal ring 30 includes four edge portions, each proximate one of the four edges of package 100. In the top view, there may not be any other conductive features, package components (such as device dies), etc., outside of wafer seal ring 30.

Referring back to FIG. 6 (also illustrated in FIGS. 19 and 20), RDLs 36 may be separated into a plurality of groups, with each of the groups encircled by one of die seal rings 40. The plurality of groups of RDLs 36 are physically separated from each other, and hence do not have the function of interconnecting package components 44, and do not have the function of interconnecting package components 64.

For example, FIG. 19 illustrates the plurality of discrete die seal rings 40 that are spaced apart from each other. The RDLs 36 encircled by a die seal ring 40 may be electrically connected to a single one of package components 44, and are not used for interconnecting package components 44. Alternatively stated, RDLs 36 do not cross-over or penetrate through (in the lateral directions in FIG. 6) the first die seal ring 40 to connect to the RDLs 36 encircled by a second seal ring 40. Rather, each of the RDLs 36 is limited in the region encircled by one die seal ring 40.

Referring back to FIG. 6, RDLs 26 may cross-over, and may overlap, die seal rings 40 to electrically interconnect the RDLs 36 that are encircled by different die seal rings 40. Accordingly, the interconnect structure 24 has the function of interconnecting different package components 44. Furthermore, interconnect structure 24 may have the function of interconnecting different package components 64. For example, when a power supply is connected into package 100 through one of connectors 64B, the power may be conducted through interconnect structure 24 to one of package components 64A (which may be an IVR), and the output of the package components 64A may be redistributed by interconnect structure 24 and provided to more than one package component 44.

As may be realized from FIGS. 19 and 20, wafer seal ring 30 and die seal rings 40 may have the same function of stiffener rings to reduce the warpage of package 100. The width W1 (FIGS. 19 and 20) of die seal rings 40 may be in the range between about 1 μm and 100 μm, and may be in the range between about 10 μm and about 20 μm. The widths W1 of die seal rings 40 may be adjusted depending on the available space and the types of package components 44. The widths W2 of wafer seal ring 30 may be in the range between about 1 μm and 100 μm, and may be in the range between about 10 μm and about 50 μm. The widths W2 of wafer seal ring 30 may be greater than or equal to the width W1 of die seal rings 40 in accordance with some embodiments.

Further referring to FIGS. 19 and 20, wafer seal ring 30 forms a full ring that is proximate the outer contour of a plurality of die seal rings 40. Wafer seal ring 30 may be free from metallic features inside the full ring and joined to the full ring. Although FIG. 19 illustrates that wafer seal ring 30 encircles and are larger than the plurality die seal rings 40, so that the wafer seal ring 30 may be distinguished easily from the plurality die seal rings 40, the wafer seal ring 30 may overlap (in the cross-sectional view in FIG. 6) the outer ones of the plurality die seal rings 40.

In accordance with some embodiments, wafer seal ring 30 is electrically grounded. In accordance with alternative embodiments, wafer seal ring 30 is electrically floating. Die seal rings 40 may also be electrically grounded or electrically floating.

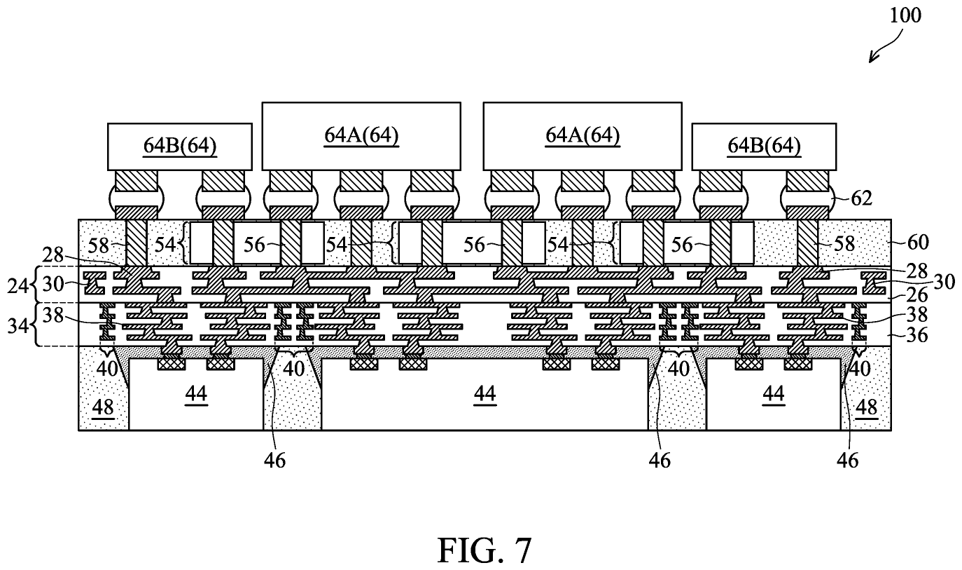

In accordance with some embodiments, as shown in FIG. 6, package components 44 may have the same lateral sizes. In accordance with alternative embodiments, as shown in FIG. 7, package components 44 may have different sizes. In accordance with some embodiments, the die seal ring 40 corresponding to (and encircling the region that overlaps) larger package components 44 may be wider than the die seal ring 40 corresponding to (and encircling the region that overlaps) smaller package components 44 to provide greater supporting force, so that the warpage caused by the larger package components 44 may be compensated for. Also, the widths of die seal ring 40 may be adjusted depending on the available space and the types of package components 44.

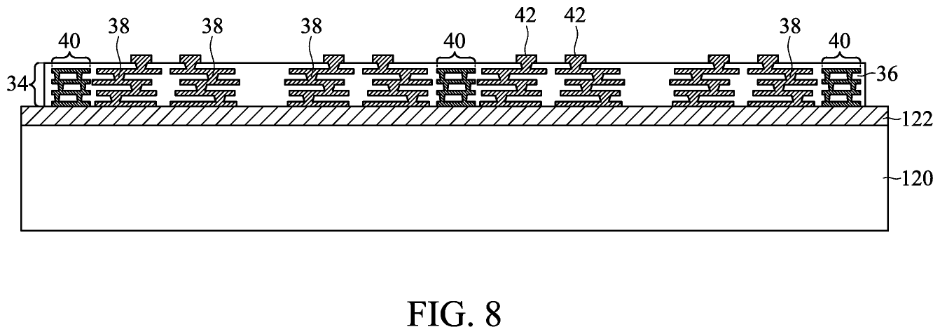

FIGS. 8-15 illustrate the formation of package 100 in accordance with alternative embodiments. These embodiments are similar to the embodiments as shown in preceding embodiments, except that the interposers 30 bonded with different package components 44 are discrete interposers, rather than a wafer-size interposer. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

Referring to FIG. 8, carrier 120 and release film 122 are provided. There may be (or may not be) a buffer layer (not shown) over release film 22. The material of the buffer layer, if formed, may be selected from PBO, polyimide, BCB, or the like.

Interposer 34 is formed over carrier 120. The formation processes, the materials, and the structures of interposer 34 may be essentially the same as shown in, and discussed referring to, FIG. 2, and are not repeated herein. Die seal rings 40 are formed in interposer 34. Electrical connectors 42 are formed at the top surface of interposer 34.

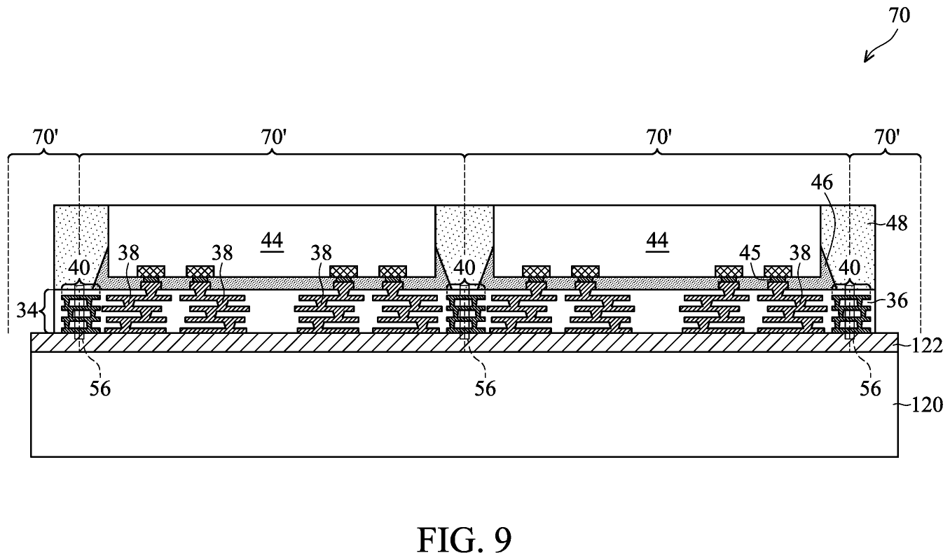

Referring to FIG. 9, package components 44 are bonded to interposer 34, for example, through solder regions 45, metal-to-metal direct bonding, or hybrid bonding that comprises both of the metal-to-metal direct bonding and fusion bonding. Underfill 46 may be dispensed into the gaps between package components 44 and interposer 34. Molding compound 48 is also dispensed. A planarization process is performed to level the top surfaces of package components 44 with the top surfaces of molding compound 48. Reconstructed wafer 70 is thus formed, which includes the structure over release film 122.

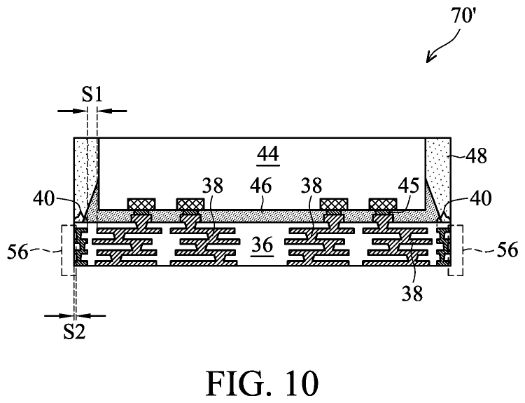

The reconstructed wafer 70 may then be de-bonded from carrier 120, for example, by projecting a laser beam on release film 122. The reconstructed wafer 70 may be placed on a dicing tape (not shown). A sawing (singulation) process may then be performed to saw the reconstructed wafer 70 to form a plurality of packages 70′. FIG. 10 illustrates one of packages 70′.

FIG. 9 illustrates where the sawing process is performed in accordance with some embodiments. Each of the package 70′ may include one or more package components 44, and a portion of the wafer-level interposer. The portions of the wafer-level interposer is also referred to as die-level interposers. In accordance with some embodiments, the lateral distance S1 (FIG. 10) between die seal ring 40 and the corresponding package components 44 may be in the range between about 20 μm and about 64 μm. Such configuration may improve the yield during singulation.

In accordance with some embodiments, the die seal rings 40 in different packages 70′ are physically and electrically connected to each other. For example, in FIGS. 9 and 10, regions 56 may include RDL lines 36 therein in accordance with some embodiments, which RDL lines 36 connect the die seal rings 40 on the left sides of regions 56 to the die seal rings 40 on the right side of regions 56. When viewed from top, the die seal rings 40 are interconnected, and may form a grid pattern same as that is as shown in FIG. 20. As a result, after the sawing process, the die seal rings 40 extend to the edges of the packages 70′, and are exposed through the sidewalls of dielectric layers 38, as shown in FIG. 10.

In accordance with alternative embodiments, the die seal rings 40 in different the reconstructed wafer 70 are physically and electrically separated each other. For example, in FIGS. 9 and 10, regions 56 may not include RDL lines 36 therein in accordance with some embodiments. The neighboring die seal rings 40 are thus separated from each other. When viewed from top, the die seal rings 40 form a plurality of discrete rings separated from each other, and thus have the same pattern as shown in FIG. 19. The sawing path (kerves) may be spaced apart from the die seal rings 40, and hence in the resulting packages 70′, the die seal rings 40 are spaced apart from the edges of the packages 70′, and are spaced apart from the edges of dielectric layers 38. The die seal rings 40 are not exposed through the edges of dielectric layers 38. These embodiments may be realized from one of ordinary skill in the art when regions 56 in FIGS. 9 and 10 are free from die seal ring therein. Spacing S2 (FIG. 10) between the edge of die seal ring 40 and the edge of package 70′ may be in the range between about 1 μm and about 10 μm in accordance with some embodiments

As may be realized from FIG. 10, die seal ring 40 forms a full ring (when viewed from top of package 70′) including four portions, with the four portions of die seal ring 40 being proximate the edges of the corresponding package 70′.

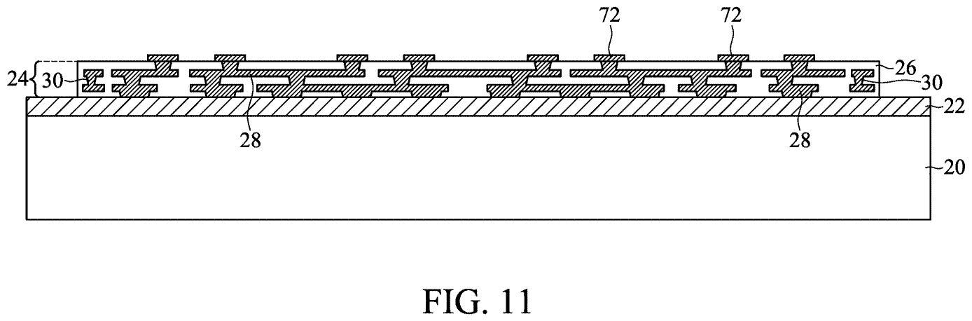

Referring to FIG. 11, carrier 20 and release film 22 are provided. Interconnect structure 24 is formed over release film 22. The details of the formation process, the materials, and the structures of interconnect structure 24 may be found referring to FIG. 1, and the details are not repeated herein. Next, electrical connectors 72 are formed as the top features of interconnect structure 24. Electrical connectors 72 may include metal pillars, metal pads, solder regions, and/or the like.

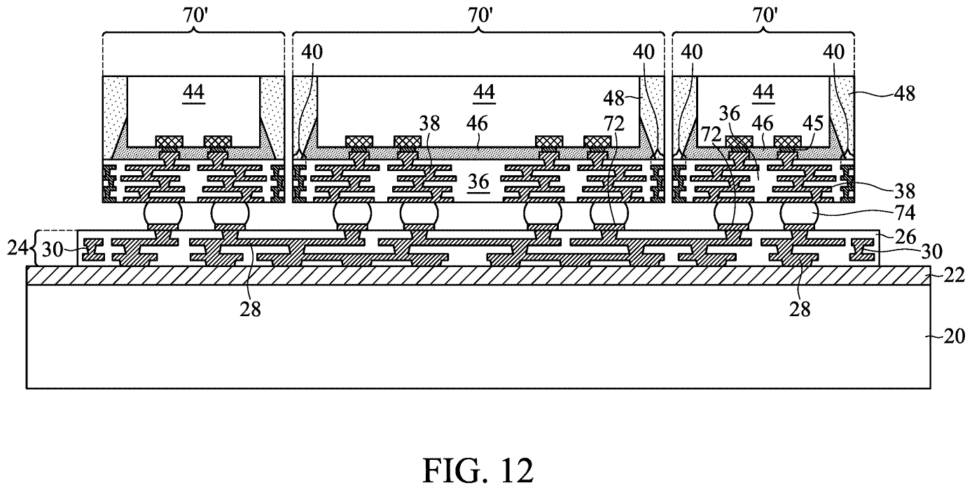

Next, as shown in FIG. 12, packages 70′ are bonded to interconnect structure 24. The bonding may be performed through solder regions 74. In accordance with alternative embodiments, the bonding may be performed through metal-to-metal direct bonding or hybrid bonding.

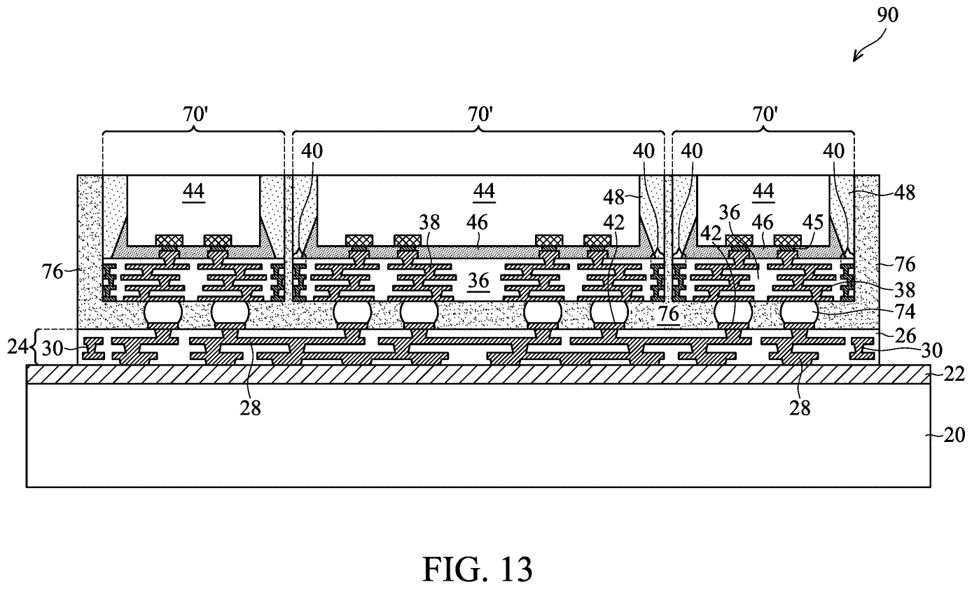

Referring to FIG. 13, packages 70′ are encapsulated in encapsulant 76, which may include a molding compound. Reconstructed wafer 90 is thus formed. In accordance with some embodiments, the packages 70′ are molded through transfer molding. The hardness of encapsulant 76 may be lower than the hardness of molding compound, which may form dielectric layers 38 in accordance with some embodiments. The lower hardness, thus softer encapsulant 76 than molding compound may help to absorb stress and to reduce the warpage of the resulting package, so that the reliability of the resulting package is improved.

Depending on whether die seal rings 40 extend to the edges of the respective dielectric layers 38 or not, encapsulant 76 may be in physical contact with the edges of die seal rings 40, and/or may be spaced apart the die seal rings 40 by the edge portions of dielectric layers 38. It is appreciated that there are a plurality of packages 70′, which may be formed separately and thus may have structures different from each other. Encapsulant 76 thus may be in physical contact with the edges of the die seal rings 40 in some of packages 70′, and spaced apart some other die seal rings 40 by the edge portions of the respective dielectric layers 38 in some other packages 70′. Throughout the description, the structure over release film 22 is referred to as reconstructed wafer 90.

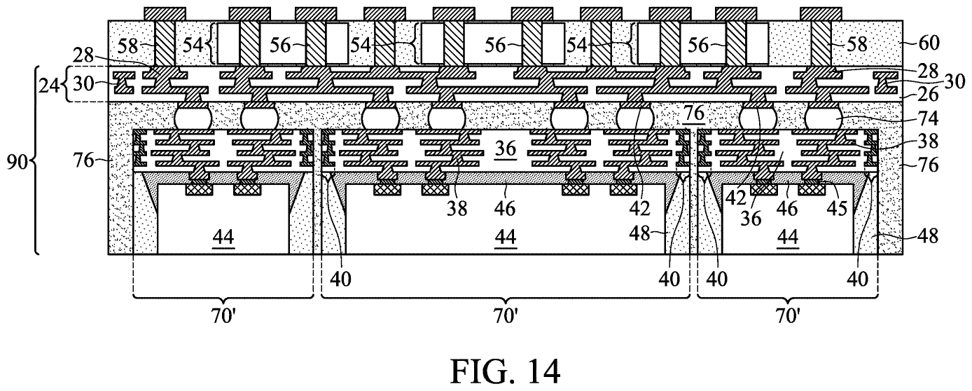

Next, reconstructed wafer 90 is de-bonded from carrier 20. The resulting reconstructed wafer 90 is shown in FIG. 14, which shows an upside-down view of the reconstructed wafer 90 in FIG. 13.

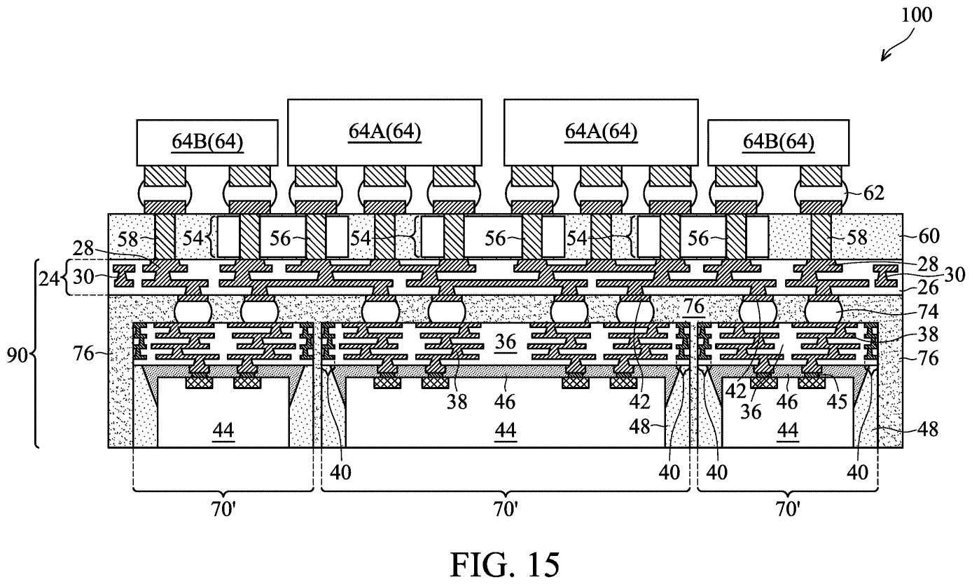

In subsequent processes, as shown in FIG. 14, LSI dies 54 are bonded, and through-vias 58 and encapsulant 60 are formed. Package components 64 are then bonded to the underlying LSI dies 54, and to form package 100, as shown in FIG. 15. Package 100 may be used as a wafer or separated into smaller packages, as discussed referring to preceding embodiments. When used (powered up) as a wafer, package 100 may be edge-trimmed or not edge-trimmed. The top view of package 100 may be shown in FIG. 19, in which packages 70′ are illustrated as an example.

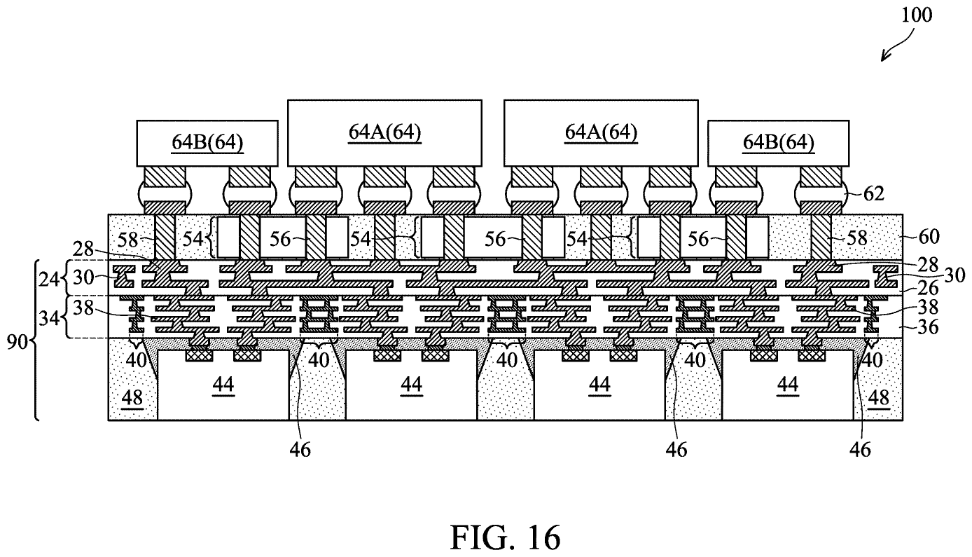

FIG. 16 illustrates package 100 in accordance with alternative embodiments. These embodiments are essentially the same as the embodiments as shown in FIG. 6, except that that die seal rings 40 are interconnected as a single and continuous structure. FIG. 20 schematically illustrates a top view of the corresponding interconnected die seal rings 40. The interconnected die seal rings 40 may form a grid in accordance with some embodiments.

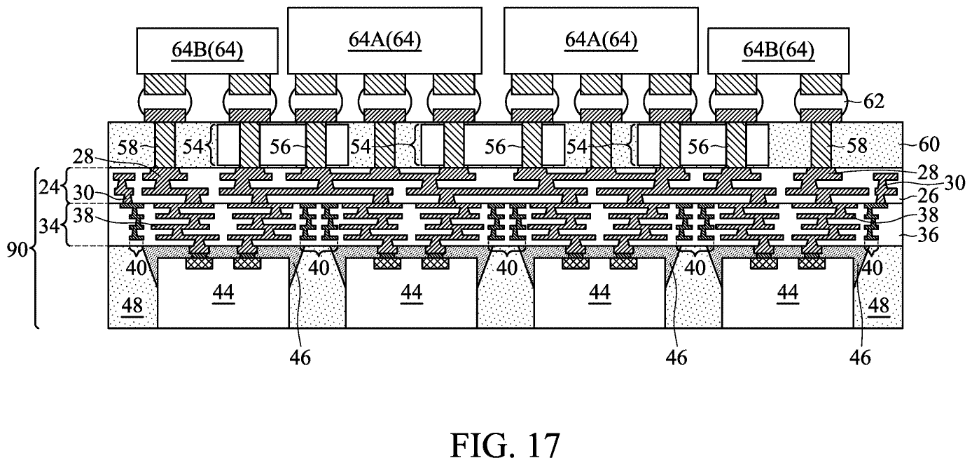

FIG. 17 illustrates package 100 in accordance with yet alternative embodiments. These embodiments are essentially the same as the embodiments as shown in FIG. 6, except that that some outer ones of die seal rings 40 close to the edges of package 100 are joined to wafer seal ring 30. In accordance with these embodiments, die seal rings 40 may be separated from each other, as illustrated. Alternatively, die seal rings 40 may be joined together as shown in FIGS. 16 and 20.

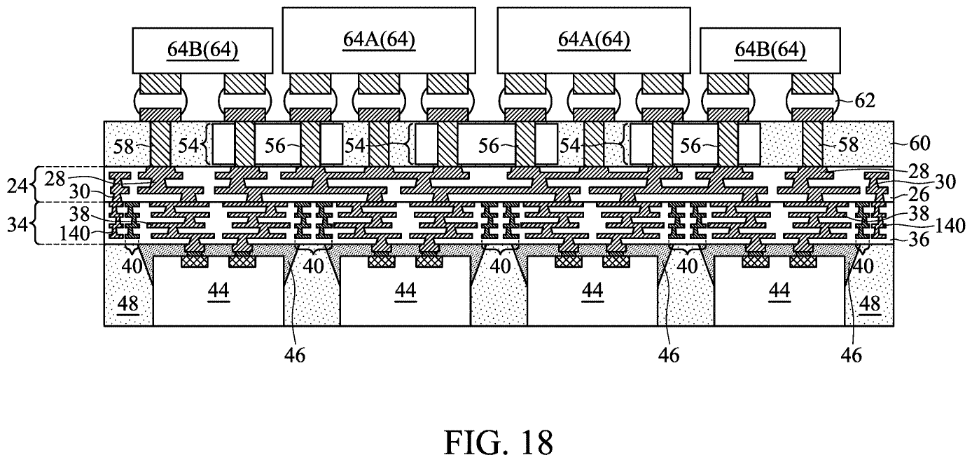

FIG. 18 illustrates package 100 in accordance with yet alternative embodiments. These embodiments are essentially the same as the embodiments as shown in FIG. 6, except that that a separate seal ring 140 is formed in interposer 34. Seal ring 140 encircles, and is separated from, all of the die seal rings 40. Wafer seal ring 30 is joined to the seal ring 140 to form a continuous seal ring that extend into both of interposer 34 and interconnect structure 24. This embodiment may also be considered as that the wafer seal ring 30 includes an extension portion extending into interposer 34.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming die seal rings and a wafer seal ring in an interposer and an interconnect structure of a package, the warpage of the resulting package is reduced. The reliability of the package is improved.

In accordance with some embodiments, a method comprises forming an interconnect structure comprising a first plurality of redistribution lines; and a wafer seal ring encircling the first plurality of redistribution lines; forming an interposer comprising a second plurality of redistribution lines; and a plurality of die seal rings encircling the second plurality of redistribution lines; bonding a first plurality of package components to the interposer; and bonding a second plurality of package components to the interconnect structure, wherein the first plurality of package components are electrically connected to the second plurality of package components through the interposer and the interconnect structure.

In an embodiment, the interconnect structure is formed over a carrier, and the interposer is formed over the interconnect structure and the carrier. In an embodiment, the method further comprises, after both of the interconnect structure and the interposer are formed, bonding the first plurality of package components to the interposer; and de-bonding the carrier. In an embodiment, the method further comprises, after the first plurality of package components are bonded to the interposer, sawing the interposer into a plurality of discrete packages, with a discrete package comprising a discrete portion of the interposer; one of the die seal rings; and one of the first plurality of package components, wherein the one of the die seal rings comprises first portions proximate peripherals of the discrete package.

In an embodiment, the method further comprises bonding the discrete package to the interconnect structure to form a package, wherein the wafer seal ring comprises second portions proximate peripherals of the package. In an embodiment, in a top view of the interconnect structure, the wafer seal ring encircles at least some of the plurality of die seal rings therein. In an embodiment, the plurality of die seal rings are physically separated from each other. In an embodiment, the plurality of die seal rings are physically interconnected.

In an embodiment, in a top view of the interposer, the second plurality of redistribution lines form a plurality of groups, each encircled by one of the plurality of die seal rings. In an embodiment, in the top view of the interposer, each of the plurality of groups is limited in a region encircled by one of the plurality of die seal rings, and in the top view, the second plurality of redistribution lines cross over the plurality of die seal rings to interconnect the plurality of groups. In an embodiment, none of the second plurality of redistribution lines include portions that extend into two of the plurality of die seal rings.

In accordance with some embodiments, a structure comprises an interposer comprising a first plurality of redistribution lines; and a plurality of die seal rings, each encircling a portion of the first plurality of redistribution lines; an interconnect structure over the interposer, wherein the interposer and the interconnect structure are comprised in a package, and the interconnect structure comprises a second plurality of redistribution lines; and a wafer seal ring proximate peripherals of the package, wherein in a top view of the structure, the wafer seal ring encircles at least some of the plurality of die seal rings; and a plurality of package components over the interconnect structure and electrically coupled to the interposer and the interconnect structure.

In an embodiment, the wafer seal ring and the plurality of die seal rings are electrically grounded. In an embodiment, the wafer seal ring is physically spaced apart from the plurality of die seal rings. In an embodiment, the plurality of die seal rings are spaced apart from each other. In an embodiment, the plurality of die seal rings are interconnected. In an embodiment, all portions of the first plurality of redistribution lines that are encircled by the plurality of die seal rings are physically separated from each other by the plurality of die seal rings, and wherein one of the second plurality of redistribution lines crosses over two of the plurality of die seal rings. In an embodiment, the wafer seal ring comprises a full ring, and is free from conductive features inside the full ring and physically joined to the full ring.

In accordance with some embodiments, a structure comprises an interposer comprising a first plurality of dielectric layers; a plurality of die seal rings in the first plurality of dielectric layers, wherein the plurality of die seal rings are electrically grounded or electrically floating; and a first plurality of redistribution lines in the first plurality of dielectric layers, wherein in a top view of the structure, the first plurality of redistribution lines form a plurality of groups that are physically separated from each other by the plurality of die seal rings; an interconnect structure over the interposer and comprising a second plurality of dielectric layers; a wafer seal ring in the second plurality of dielectric layers, wherein the wafer seal ring is electrically grounded or electrically floating; and a second plurality of redistribution lines in the second plurality of dielectric layers, wherein the second plurality of redistribution lines interconnect two of the plurality of groups; a plurality of package components under the interposer and electrically coupled to the interposer and the interconnect structure; and a bridge die over and electrically coupled to the interposer and the interconnect structure.

In an embodiment, the interposer, the interconnect structure, and the plurality of package components are comprised in a package, and the wafer seal ring is proximate peripheral regions of the package, and wherein in the top view of the structure, some of the plurality of die seal rings are encircled by the wafer seal ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
an interposer comprising:
a first die seal ring and a second die seal ring; and
a first plurality of redistribution lines and a second plurality of redistribution lines in the first die seal ring and the second die seal ring, respectively;
an interconnect structure over the interposer, the interconnect structure comprising:
a wafer seal ring, wherein in a top view of the structure, the wafer seal ring encircles chip areas occupied by the plurality of die seal rings; and
a third plurality of redistribution lines in the wafer seal ring; and
a plurality of package components over the interconnect structure and electrically coupled to the first plurality of redistribution lines and the second plurality of redistribution lines through the third plurality of redistribution lines.

2. The structure of claim 1, wherein in the top view of the structure, the wafer seal ring encircles the first die seal ring and the second die seal ring.

3. The structure of claim 1, wherein the interposer comprises a plurality of dielectric layers, with the first die seal ring and the second die seal ring being in the plurality of dielectric layers, wherein first portions of the plurality of dielectric layers that embed the first die seal ring and second portions of the plurality of dielectric layers that embed the second die seal ring are parts of same continuous dielectric layers.

4. The structure of claim 1, wherein the interposer and the interconnect structure are comprised in a same package.

5. The structure of claim 4, wherein in the top view, the wafer seal ring comprises portions proximate peripherals of the same package.

6. The structure of claim 1, wherein the wafer seal ring is electrically disconnected from the first die seal ring and the second die seal ring.

7. The structure of claim 1, wherein the wafer seal ring is physically joined to the first die seal ring, and is electrically disconnected from the second die seal ring.

8. The structure of claim 1, wherein the wafer seal ring and the plurality of die seal rings are electrically grounded.

9. A structure comprising:
an interposer comprising:
a first plurality of dielectric layers;
a plurality of die seal rings in the first plurality of dielectric layers, wherein the plurality of die seal rings are physically separated from each other by parts of the first plurality of dielectric layers; and
a first plurality of redistribution lines in the first plurality of dielectric layers, wherein in a top view of the structure, the first plurality of redistribution lines form a plurality of groups that are in the plurality of die seal rings;
an interconnect structure over the interposer and comprising:
a second plurality of dielectric layers;
a wafer seal ring in the second plurality of dielectric layers, wherein in the top view of the structure, the wafer seal ring encircles chip areas that are encircled by the plurality of die seal rings; and
a second plurality of redistribution lines in the wafer seal ring, wherein the second plurality of redistribution lines interconnect two of the plurality of groups;
a first plurality of package components under the interposer; and
a second plurality of package components over the interconnect structure and electrically connected to the first plurality of package components through the interposer and the interconnect structure.

10. The structure of claim 9, wherein the wafer seal ring and the plurality of die seal rings are electrically grounded or electrically floating.

11. The structure of claim 9, wherein the wafer seal ring is joined to a first seal ring of the plurality of die seal rings.

12. The structure of claim 11, wherein the wafer seal ring is physically separated from a second seal ring of the plurality of die seal rings.

13. The structure of claim 9, wherein in the top view of the structure, the wafer seal ring encircles the plurality of die seal rings.

14. The structure of claim 9, wherein the plurality of die seal rings are physically separated from each other, and are electrically interconnected.

15. The structure of claim 9, wherein the first plurality of dielectric layers continuously extend throughout the plurality of die seal rings.

16. A structure comprising:
an interposer comprising:
a first plurality of dielectric layers;
a first die seal ring and a second die seal ring in the first plurality of dielectric layers; and
a first group of redistribution lines and a second group of redistribution lines in the first die seal ring and the second die seal ring, respectively;
an interconnect structure over the interposer, the interconnect structure comprising:
a wafer seal ring; and
a third plurality of redistribution lines in the wafer seal ring;
a first package component and a second package component over the interconnect structure; and
a third package component and a fourth package component under the interposer, wherein the first package component is electrically coupled to the third package component through the first group of redistribution lines and the wafer seal ring, and the second package component is electrically coupled to the fourth package component through the second group of redistribution lines and the wafer seal ring.

17. The structure of claim 16, wherein in a top view of the structure, the wafer seal ring encircles the first die seal ring and the second die seal ring.

18. The structure of claim 16, wherein the first plurality of dielectric layers continuously extend to both of the first die seal ring and the second die seal ring.

19. The structure of claim 16, wherein the first die seal ring is physically separated from the second die seal ring by portions of the first plurality of dielectric layers.

20. The structure of claim 19, wherein the interconnect structure further comprises a second plurality of dielectric layers continuously extending from a first region overlapping the first group of redistribution lines to a second region overlapping the second group of redistribution lines.
